(19) United States
(12) Patent Application Publication
(10) Pub. No.: US 2005/0229947 A1
(43) Pub. Date: Oct. 20, 2005

(54) Methods of inserting or removing a species from a substrate

(75) Inventors: Jeffrey J. Spiegelman, San Diego, CA (US); Daniel Alvarez JR., San Diego, CA (US); Joshua T. Cook, Encinitas, CA (US)

Correspondence Address: HAMILTON, BROOK, SMITH & REYNOLDS, P.C., 530 VIRGINIA ROAD, P.O. BOX 9133, CONCORD, MA, 01742-9133, US

(73) Assignee: Mykrolis Corporation, Billerica, MA (US)

(21) Appl. No.: 11/036,585

(22) Filed: Jan. 13, 2005

Related U.S. Application Data
(63) Continuation-in-part of application No. 10/692,019, filed on Oct. 23, 2003, now Pat. No. 6,869,463.
Application No. 10/692,019 is a continuation of application No. 10/173,335, filed on Jun. 14, 2002, now Pat. No. 6,638,341.

(51) Int. Cl. H01L 21/44

(52) U.S. Cl. 134/2; 134/10

(57) ABSTRACT

Methods of inserting and removing species from substrates utilizing pressure-vent cycling are revealed in embodiments of the invention. Various embodiments introduce a fluid to a vessel containing the substrate while setting pressure at an elevated level. The pressure is maintained at the elevated level for a predetermined period of time, the lowered by removing fluid from the vessel. The steps of introducing fluid, maintaining pressure, and lowering pressure are repeated at least once. Embodiments of the invention may allow a species to be removed from the voids of a substrate, or allow a new species to be inserted into the voids. Particular embodiments also have special application to preconditioning, activating, and/or regenerating gas purification substrates, or removing and/or delivering species with respect to semiconductor substrates. Embodiments of the invention allow faster transport of species to and from substrates with less use of purging or filling fluids.

### RELATED APPLICATIONS

This application is a continuation-in-part of co-pending U.S. application Ser. No. 10/692,019 filed Oct. 23, 2003; which is a continuation of U.S. application Ser. No. 10/173,335 filed Jun. 14, 2002, which issued as U.S. Pat. No. 6,638,341 on Oct. 28, 2003. The entire teachings of both applications are hereby incorporated by reference herein.

### BACKGROUND OF THE INVENTION

In past gas purification processes, activation and preconditioning gases have been flowed through a vessel and across a gas purification substrate, having reached into the pores of the substrate by mass transfer/molecular diffusion. Very long activation or preconditioning periods have been required since such diffusion occurs slowly, particularly as the gas traverses into greater depths of the pores. It is quite common for it to require 24 to 48 hours for satisfactory activation or preconditioning of an entire substrate to be accomplished by flow-generated mass transfer/molecular diffusion. In addition, such diffusion does not provide thorough activation or preconditioning, since as a pore narrows over its length, there is greater resistance to diffusion of the purging or activating gas through it, such that many sites requiring activation or areas requiring purging of packing gases simply cannot be reached by the slowly diffusing gas within a reasonable period of time. During prolonged preconditioning or activation periods required, it is not uncommon to have excessive exotherms occur within the substrate. In order to avoid such exotherms (which could damage the substrates) it is often necessary to limit the flow rate of the purging gas through the vessel, thus also reducing the rate of diffusion of the purging gas into the pores and prolonging the activation or preconditioning time period.

The problems with transport of gases into pores, however, is not limited to gas purification substrates. Indeed, penetration of gases into voids of other substrates (e.g., catalysts) and deep trench features of wafers used in semiconductors are limited by similar concerns.

Forced convection purging of equipment has been used in some of the chemical and petroleum industries, but it has been with respect to macro-scale processes in which only relatively coarse and limited removal of packing gases or limited activation of active sites has been required. Such has not previously been known in or believed applicable to gas purification reactors and vessels, or other types of substrates, in which ultra-high purity (less that 100 parts per billion contamination) must be accomplished.

### SUMMARY OF THE INVENTION

In one embodiment of the invention, a method for removing a species from a semiconductor substrate is described. The method includes the step of introducing a purging fluid into a vessel that contains the semiconductor substrate. The pressure in the vessel is set at an elevated level, and maintained at that level for a predetermined period of time. The pressure in the vessel is then lowered to a lower level by removing fluid from the vessel that includes the species. The steps of introducing the purging fluid, maintaining the pressure in the vessel, and lowering the pressure are repeated at least once more, the repetition of the set of steps thereby removing the species from the semiconductor substrate.

In related embodiments of the invention, the species may be removed from within a structural feature of the semiconductor substrate. The structural feature may have an opening size smaller than a penetration dimension of the feature, be a high aspect ratio feature, have a size smaller than about 100 nm, or have a size larger than about 50 nm. The species to be removed may be water, isopropyl alcohol, a hydrocarbon, and residual acids and bases. The purging fluid may include nitrogen, helium, carbon dioxide, trimethylsilyl chloride, hexamethyl disilazane, dry air, oxygen, water, or mixtures thereof. The semiconductor substrate may be a low k dielectric material. The lower level of pressure may be subatmospheric. The method may be modified such that either the step of introducing the purging fluid or maintaining the pressure may also repair damage to the semiconductor substrate, or to a structural feature of the substrate, by exposing the substrate to the purging fluid. The step of introducing the purging fluid or maintaining the pressure may also passivate a surface of the semiconductor substrate by exposing the substrate to the purging fluid. Either step may also cause a chemical reaction involving the purging fluid; the reaction may also produce the species to be removed. The step of lowering the pressure may also selective remove a species from the semiconductor substrate. The repetition of introducing the purging fluid, maintaining the pressure, and lowering the pressure may include changing the elevated level, the lower level, or the predetermined period of time during at least one repetition. As well, a second purging fluid, different in composition than the initial purging fluid, may be used in place of the initial purging fluid during at least one of the subsequent repetitions.

In another embodiment of the invention, a new species is delivered to a semiconductor substrate. The method includes the step of introducing a filling fluid comprising the new species in a vessel containing the semiconductor substrate. The pressure in the vessel is set at an elevated level and maintained for a predetermined period of time. The pressure is lowered to a lower level by removing fluid from the vessel. The steps of introducing the filling fluid, maintaining the pressure, and lowering the pressure are repeated at least once to deliver the species to the semiconductor substrate. Related embodiments include features described in embodiments related to removing a species from a semiconductor substrate.

In a third embodiment of the invention, a method of removing a species from a substrate is presented. The method includes the steps of introducing a purging fluid, substantially free of the species, into a vessel containing the substrate. The pressure in the vessel is set at an elevated level, and maintained for a predetermined period of time. The pressure is lowered to a lower level by removing fluid from the vessel, the fluid including the species, the species being removed from voids in the substrate. The steps of introducing the filling fluid, maintaining the pressure, and lowering the pressure are repeated at least once to remove the species from the substrate. Alternatively, the substrate may be characterized by a surface area of at least about 1 m²/g with or without reference to a void structure.

The voids of the substrate may be in the nanoporous, mesoporous, microporous, or macroporous size range. The voids may have an opening size smaller than a penetration dimension of the void. The temperature in the vessel may be maintained in the range of about 50° C. to about 400° C. The steps of introducing the filling fluid, maintaining the pressure, and lowering the pressure may be repeated between about 50 times to about 500 times. The predetermined period of time may be for a period of about 1 second to about 10 minutes. The purging fluid may be a bulk gas, a specialty gas, or a fluid mixture (e.g., one fluid present in a concentration range of about 50 ppm to about 5% of the mixture). The purging fluid may include hydrogen, oxygen, nitrogen, argon, hydrogen chloride, ammonia, air, carbon dioxide, helium, silane, germane, diborane, phosphine, arsine or mixtures thereof (e.g., about 5% hydrogen and about 95% nitrogen). The species to be removed may include oxygen, hydrogen, carbon monoxide, carbon dioxide, water, a non-methane hydrocarbon, or an oxidation byproduct. The step of introducing the purging fluid or maintaining the pressure may also include causing a chemical reaction to form the species in the voids of the substrate. The method steps may be repeated until the temperature in the vessel passes through a maximum value and decreases to a substantially constant equilibrium value. As well, the repetition of method steps may also include changing the elevated level of pressure, the lower level of pressure, or the predetermined period of time to maintain the pressure during at least one of the repetitions. Also, a second purging fluid, different in composition than the initial purging fluid, may be used in place of the initial purging fluid during at least one of the subsequent repetitions.

In a fourth embodiment of the invention, a method of inserting a new species into a substrate is presented. The method includes introducing a filling fluid comprising the new species into a vessel containing the substrate. The pressure in the vessel is set at an elevated level. The substrate having voids. The pressure is maintained at the elevated level for a predetermined period of time; the new species being inserted into the voids. The pressure is then lowered to a lower level by removing fluid from the vessel. The steps of introducing the filling fluid, maintaining the pressure, and lowering the pressure are repeated at least once to insert the new species into the substrate.

The substrate may have an inorganic oxide surface, have a surface area of at least about 1 m²/g, or have voids which have an opening size smaller than a penetration dimension of the voids. Hydrogen or one or more inert gases may be used as a filling fluid. The step of introducing the filling fluid or maintaining the pressure may also cause a chemical reaction in the voids involving the new species. As well, the elevated level of pressure, the lower level of pressure, or the predetermined time for maintaining the pressure may be changed during at least one repetition of the repeated steps of the method.

In a fifth embodiment of the invention, a method for regenerating a gas purification substrate is presented. The method includes introducing a purging fluid into a vessel containing the gas purification substrate. The pressure in the vessel is set to an elevated level, and maintained at the elevated level for a predetermined period of time. The pressure in the vessel is then lowered to a lower level by removing fluid from the vessel. The steps of introducing the purging fluid, maintaining the pressure, and lowering the pressure are repeated at least once more to regenerate the as purification substrate.

### BRIEF DESCRIPTION OF THE DRAWINGS

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIG. 1 is a graph from a typical prior art preconditioning process for an ammonia purification vessel using gas-flow-generated mass transfer/molecular diffusion, showing the comparison of quantity of purging gas used versus temperature reached.

FIG. 2 is a graph from a preconditioning process for an ammonia purification vessel using the forced convention of the present invention, also showing the comparison of quantity of purging gas used versus temperature reached.

FIG. 3 is a composite of FIG. 1 and FIG. 2 showing the direct comparison of the forced convection data (left edge of the graph; triangles) of this invention with data from the prior art diffusion process (extending all the way across the graph; closed circles).

FIGS. 4A-4D are diagrammatic representations of void configurations in which the size of each void opening is smaller than the penetration dimension of the corresponding void.

### DETAILED DESCRIPTION OF THE INVENTION

Activating and Preconditioning Gas Purification Substrates

The presence of a packing gas in the pores of a gas purification substrate blocks access of the contaminated gas therein to many of the active removal sites on the surface of the substrate. The packing gas may be removed by purging the packing gas and saturating the substrate with purging gas, usually with the same gas as will be purified or a component thereof, before the substrate may be used for gas purification. This removal and replacement process is commonly referred to as “preconditioning” of the substrate. There is an equivalent process used when the active sites on a gas purification substrate are of only limited decontamination activity initially. Such sites must be “activated” by contacting them with an activating gas, causing them to become much more active for decontamination. Thus the purging gas must be forced to as many of the activation sites as possible during activation. A particular substrate may require both activation and preconditioning, which may occur simultaneously or in sequence, and may be accomplished either by different gases or by the same gas.

One embodiment of the present invention comprises the use of forced convection of a purging gas to activate sites throughout the pores and surface of a gas purification substrate and/or to purge a packing gas from a substrate, all in a small fraction of the time previously required for preconditioning or activation by diffusion and with use (and resulting waste by venting) of only a small fraction of the purging gas previously needed by the prior art diffusion processes.

In the present process, the purging gas (which may be the activation gas, the preconditioning gas or a gas which serves both purposes) is pumped into the substrate-containing vessel, raised to an elevated pressure and maintained at that pressure for a short predetermined time, following which the contents of the vessel are vented to the atmosphere or to an “atmospheric” pressure collection vessel. Promptly thereafter more purging gas is pumped into the substrate-containing vessel and raised to elevated pressure, maintained at elevated pressure for a short determined time, followed by venting of the vessel contents to the atmosphere or an atmospheric pressure vessel. This cycle is repeated for as many times as necessary to reach the desired level of activation of the active sites of the substrate and/or for removal of substantially all packing gas within the substrate. If during the preconditioning a chemical reaction also occurs which generates moisture and/or another gaseous byproduct, the cycles should continue until the chemical reaction has reached completion and all generated byproduct is also purged from the system. The repeated process is referred to herein as the “pressure-vent cycle”.

We have found that the pressurize-and-vent cycle is conveniently repeated at least two times, and preferably at least four times, and more preferably at least ten times. There is no absolute maximum number of cycles, but in practice about 200 cycles should be sufficient for activation or preconditioning of almost all substrates, and in many cases significantly less cycles (from about 10 to about 100) will be quite adequate. The pressurization is preferably raised to and maintained at a level of about at least two times the “atmospheric” pressure, and preferably about at least five times the atmospheric pressure. Normally each cycle will be performed at the same elevated pressure level, but that is not required. By “atmospheric” pressure is meant the pressure of the environment into which the gas in the vessel is vented following the pressurization portion of a cycle, which may conveniently be the open ambient environment or a capture vessel. Preferably however, the vessel will be vented to a subatmospheric environment, in particular using a strong vacuum, which may be as low as about 10⁻⁷ torr (1.33×10⁻⁵ Pa). The important criterion is that the pressure differential between the elevated pressure during pressurization and the pressure upon venting should be at least two times, and preferably at least five times, the vented pressure. There is no absolute maximum differential, and it is contemplated that differentials as high as about 10¹⁰ times are feasible.

Vacuum venting differentials of 10⁸ are convenient, though with atmospheric venting the differentials are more usually on the order of 10⁴. The object is to have sufficiently high pressure during the elevated pressurization period to force the purging gas into and through essentially all parts of the substrate including the narrowest portions of the pores and into any small cul-de-sacs within the pores, and then upon venting to have a sufficiently high pressure differential so that most of the contents of the vessel will be evacuated quickly and thoroughly during the venting. The vessel contents being evacuated will contain not only a substantial amount of the purging gas but also a substantial amount of any packing or other gas which the purging gas will have displaced during the pressurization phase of the cycle.

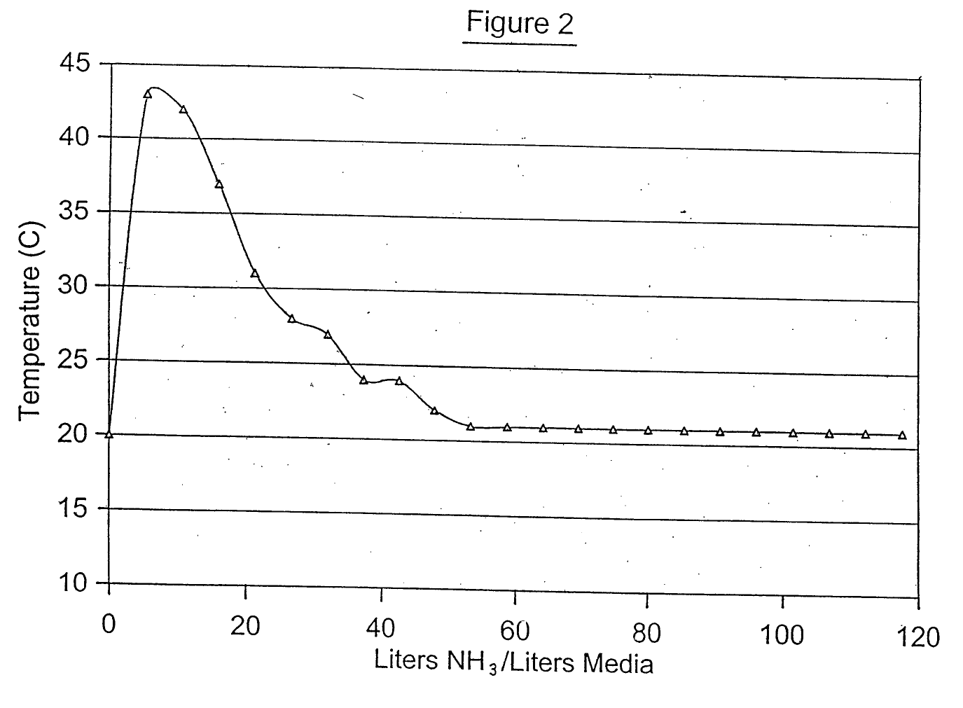

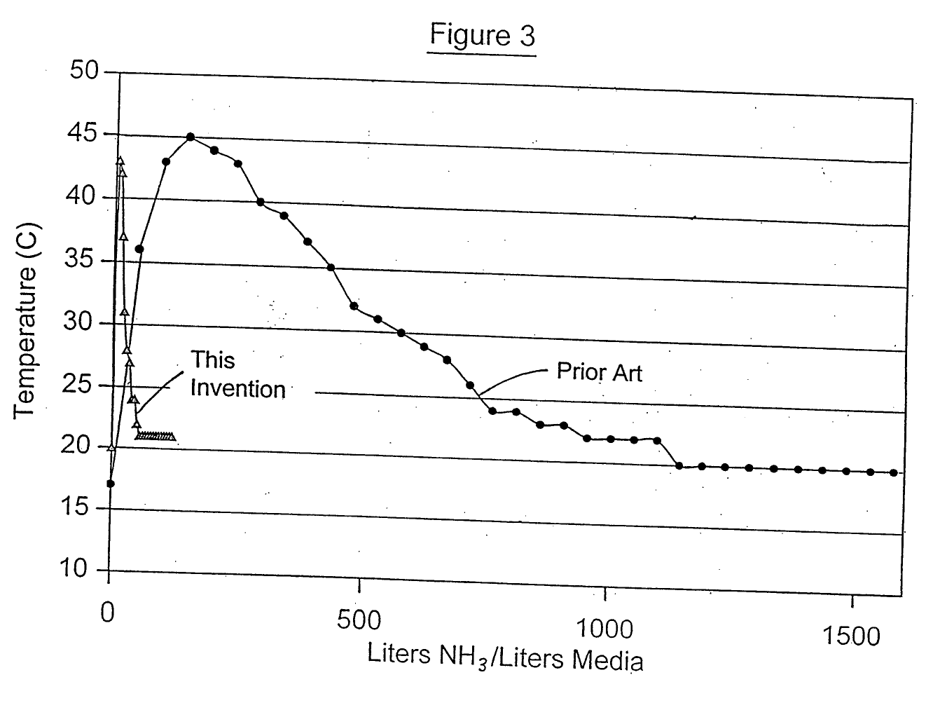

Each cycle is relatively short. The amount of hold time at the elevated pressure will generally be in the range of about ten seconds to about ten minutes. Additional hold time is not usually advantageous, since the forced convection mechanism works most efficiently through multiple repeated cycles than by having extended times within each single cycle. Having relatively short cycles also significantly limits any occasion for an excessive exothermic reaction during any individual cycle. There will normally be a small exotherm that occurs during the first few cycles, as will be seen in FIGS. 2 and 3, but that exotherm normally dissipates quickly as most of the packing gas becomes removed and most of the sites become preconditioned or activated during the early part of the process.

Embodiments of the present invention are useful to prepare substrates for use in a wide variety of gas purification processes, including those for purifying both bulk gases and specialty gases. Among the bulk gases that can be purified in processes for which embodiments of the present invention provide initial activation and/or preconditioning are hydrogen, oxygen, nitrogen, argon, hydrogen chloride, ammonia, air, carbon dioxide and helium. Specialty gases included silane, germane, diborane, phosphine and arsine. All of these gases may also be in mixtures having any combination of the above-mentioned gases or with other gases, such as mixtures (blends) of the speciality gases with hydrogen, nitrogen or argon as the carrier gas, especially in which the dopant (non-carrier) gas concentration is from about 50 ppm up to about five percent of the mixture. It is preferred that the gas or gas mixture to be decontaminated will be the same as the gas or gas mixture to be used for purging to accomplish preconditioning or activation, but embodiments of the present invention may also utilize a nonidentical gas in the purging if its continued presence after purging or activation will not adversely affect the purification of the contaminated gas. Thus for instance, where the gas to be decontaminated is a mixture with a small concentration of the dopant gas, it might be desired to precondition with the principal component of the mixture (i.e., the carrier gas in this case) alone as long as the substrate does not thereafter act to reduce the concentration of the dopant gas in the mixture during decontamination.

Embodiments of the present invention find significant application in the preconditioning and/or activation of substrates used in gas purification processes and equipment in which the treated gas or gas mixture is to be decontaminated down to a level of no greater than about 1 ppm of contaminants, preferably down to a level on the order from about 1 ppb to about 10 ppb of contaminants, and more preferably down to a level on the order from about 1 ppt to about 100 ppt.

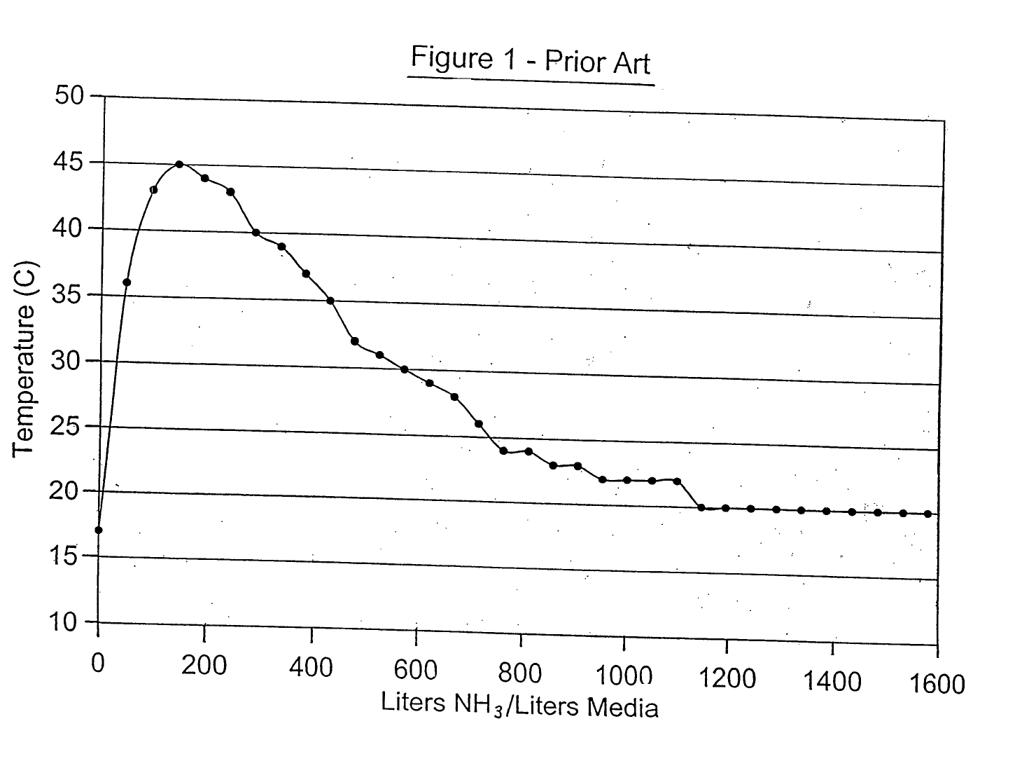

The superiority of this process is illustrated in FIGS. 1, 2 and 3, which illustrate preconditioning with ammonia to purge an ammonia decontamination substrate of packing gas (nitrogen). It is conventional to determine completion of preconditioning in a practical sense by monitoring the temperature of the interior of the vessel. An exotherm occurs early in the preconditioning process as the packing gas is displaced. As the concentration of the packing gas decreases the exotherm dies away and the interior of the vessel reaches an equilibrium temperature (which in the case of ammonia is about 20° C. [68° F.]), indicating that little or no significant amount of the packing gas is still present and being purged. When the equilibrium temperature has been reached and maintained for a period sufficient to confirm its presence to the operator, the preconditioning process is deemed complete. The flow of contaminated gas can then be started and the decontamination process will commence.

In FIG. 1 the substrate is shown as being preconditioned with ammonia by prior art continuous gas flow through the vessel to produce mass transfer/molecular diffusion of the ammonia through the pores of the substrate. It will be seen that almost 1200 liters of ammonia per liter of substrate must be flowed through the vessel before the exotherm reaches its equilibrium temperature level, and another 200-400 liters must be used before the presence of the equilibrium temperature is confirmed sufficiently to warrant halting the preconditioning process. The overall time involved in the process shown in FIG. 1 was 9.5 hours to initially reach the equilibrium temperature and 2.5 hours to reach a point at which the operator could reasonably conclude that equilibrium temperature had in fact been established.

Using an embodiment of the present invention, however, as illustrated in FIG. 2, the system is cycled through 10-11 cycles (each data point) before the equilibrium temperature level is reached, and only about 5 or so more before that level is confirmed, with the total use of only 60-80 liters of ammonia per liter of substrate, a 20-fold improvement over the prior art diffusion system of FIG. 1. Also the exotherm reached (43-45° C. [110°-113° F.]) is no greater than is reached by the prior art diffusion process preconditioning. Of equal significance with respect to the superiority of this embodiment of the invention is that there was a five-fold decrease in the amount of times needed to reach the initial equilibrium temperature and confirmation point, as compared to the times needed for the prior art diffusion preconditioning process of FIG. 1.

The two graphs of FIGS. 1 and 2 are shown on the same grid in FIG. 3. The dramatic reduction in ammonia usage (and also in preconditioning time) is evident in FIG. 3. It will be seen that the diffusion purging process has used more ammonia (and used more time) just for its first stage—reaching the peak of its exotherm—than forced convection purging for completion of preconditioning, including the period needed to confirm that the equilibrium temperature had been reached. Thus embodiments of the invention can accomplish preconditioning in a small fraction of the time and with a small fraction of the gas usage relative to the prior art diffusion preconditioning processes.

Not directly shown in the Figures but evident from them is the important improvement in costs of some embodiments the present invention. It will be recognized that gas used for preconditioning cannot be recovered for use as a decontaminated manufacturing process gas, since upon exiting the vessel it will be contaminated with the packing gas or other materials from within the vessel which it has displaced within the substrate. Not until the preconditioning process is complete can usable manufacturing process gas be obtained from the gas purifier. Since as noted above one normally uses the same gas (or gas mixture) to precondition as will be used in the subsequent purification operation, the amount of gas used during preconditioning represents direct economic loss to the system operator. Thus in the examples shown in the Figures, the operator of the diffusion preconditioning process has lost some 1200 or more liters of ammonia while the operator of the present forced convention preconditioning process has lost only 60-80 liters. Even with a common gas such as ammonia, the economic value disparity is significant, and it will of course be much greater when the gases used are expensive mixtures or speciality gases.

The nature of the gas decontamination vessel is not critical, nor is the nature of the substrate. Each will be determined by the physical and chemical properties of the gas to be purified, and since in the preferred mode the purified gas will also be the gas used as the activating and/or preconditioning gas, there will not be any problem of incompatibility or of adverse effects with the forced convection preconditioning and/or activation embodiments of the present invention.

Numerous different gas decontamination vessels and substrates for a wide variety of gases and gas mixtures are available commercially, including those available from Mykrolis Corp. of San Diego, Calif. For example, the commercially available gas purifiers utilize gas purification substrates with a variety of media including inorganic, inorganic oxide, or a nickel metal media. Such substrates may be used to remove a variety of contaminants including oxygen, hydrogen, carbon monoxide, carbon dioxide, water, and non-methane hydrocarbons. The substrates are purified by cycling between an elevated pressure and a lower pressure from about 50 to about 500 times. The elevated pressure is maintained for a predetermined period ranging from about 1 second to about 10 minutes, the substrate being exposed to a temperature of about 50° C. to about 400° C. throughout the pressure-vent cycling process.

Purifiers with inorganic oxide media are activated with nitrogen gas. Purifiers utilizing other types of inorganic media or nickel metallic media are activated using a combination of nitrogen and hydrogen. For example, inorganic oxide media may be used to extract oxygen contaminants. Such species are removed by first exposing the media to pressure-vent cycling with hydrogen. The cycling inserts hydrogen to sites of the media with the oxygen contaminants, allowing oxidation state reduction at the sites to create water. The water is subsequently removed by pressure-vent cycling using nitrogen as the purging gas. Alternatively, a mixture of hydrogen and nitrogen gases (e.g., a mixture of about 5% hydrogen gas and about 95% nitrogen gas) may be utilized to achieve both the oxidation state change and water purge simultaneously.

From the foregoing discussion, the methods discussed herein for preconditioning or activating gas purification substrates can be couched as a method that removes one or more particular species (e.g., packing gases from a substrate) or inserts one or more particular species (e.g., a component of a purging gas), either method relying upon the same transport phenomena. When the method is used to insert a new species into a substrate, the “purging” gas also becomes a “filling” gas that carries the new species. Alternatively, the new species may be the filling gas itself. Also, the transport of species to and away from the substrate depend upon the pressure-vent cycling conditions (e.g., the values of the cycled pressure, the time the substrate is exposed to a pressure, and the number of cycles), and not upon the mechanisms utilized to achieve the particular pressure-vent cycling conditions (e.g., use of an evacuation chamber or any particular vessel).

In a specific example, methods of removing species may be applied to various substrates, such as gas purification substrates, for regeneration. In the context of gas purification substrates, substrates saturated with contaminants may be regenerated by exposing the substrates to a purging gas to remove the contaminants, and thus preparing the substrate to be used subsequently for decontamination. By utilizing pressure-vent cycling, the gas purification substrates may be regenerated using less purging gas, and using less time, than simply exposing the substrates to a constant flow purging gas. Regeneration may also entail the purging gas interacting with the substrate or contaminants or other species in a manner to condition the substrate to accept contaminants again.

Pressure-Vent Cycling Applied to Substrates Generally

Though the foregoing discussion described particular embodiments of the invention directed toward gas purification substrates, the scope of the invention may be broadened both in the context of gas purification substrates, and in application to other types of substrates. Thus, embodiments of invention previously directed to methods for preconditioning and activation of gas purification substrates may also be applied to other embodiments of the invention as described herein (e.g., methods corresponding to specific pressures, holding times for pressures, temperature monitoring, number of cycling repetitions, types of substrates, types of filling fluids, etc.).

In one embodiment of the invention, steps of a method for gas purification media preconditioning and/or activation are applied to a substrate having voids to remove one or more species, without regard to a particular application. Such an embodiment includes introducing a purging fluid into a vessel that contains the substrate, while setting the pressure in the vessel at an elevated level. The pressure is maintained at the elevated level for a predetermined period of time before being lowered to a lower level. The pressure is lowered by removing fluid from the vessel, the fluid also including the species to be removed. The set of steps including introducing the purging fluid, maintaining the pressure for a predetermined period of time, and lowering the pressure are carried out at least once more, each set representing a pressure-vent cycle.

Species to be removed may include particular chemical entities or physical entities (e.g., particulates). Though practice of the method may utilize gases, the fluids of the method may be gases, supercritical fluids, liquids, or a combination thereof. The fluids may also carry particulate matter.

Embodiments of the invention utilize pressure-vent cycling to remove species in the void structure of substrates. As discussed with regard to gas purification substrates, the pressure-vent cycling induces forced convection, allowing removal of species in a much shorter period of time, and with less purging gas, than utilized in steady gas flow driven processes. Substrates having particular structures may be especially susceptible to accelerated species removal with pressure-vent cycling.

For example, voids of a substrate may be configured such that the substrate possesses a substantial surface area and small morphological features. Measurement techniques such as the BET method allow a characterization of the surface area. Some substrates, such as a wafer surface, have a specific area in a range of about 1 m²/g and greater. Other substrates may have even higher specific surface areas (e.g., particular gas purification substrates having a specific surface area of about 100 m²/g or greater). Species associated with void sites in such substrates may be difficult to remove due to the development of a boundary layer created under steady fluid flow conditions; the boundary layer limiting transport of the species away from the local area of the void site. Removal of the species may be accelerated using forced convection, as induced by pressure-vent cycling, since each pressure-vent cycle changes the boundary layer structure. Such changes enhance species transport relative to a steady fluid flow situation. Similarly, substrates having a high surface area are also encompassed by embodiments of this invention without regard to having a substantial volume of void space relative to the volume of the entire substrate (e.g., a slab substrate with a very rough surface).

In another example, the voids of a substrate may be pores associated with a porous substrate. Nanoporous substrates are generally defined as porous materials with pores smaller than 100 nm (Abstract, Lu, G. Q. and Zhao, X. S., Nanoporous Materials: Science and Engineering, Imperial College Press, ISBN 1-86094-210-5, scheduled publication Winter 2004). As defined by the IUPAC, porous substrates can be classified by the sizes of the pores in the substrate (Manual of Symbols and Terminology for Physicochemical Quantities and Units, Appendix II Definitions, Terminology and Symbols in Colloid and Surface Chemistry (1971), prepared for Internet Consultation (2001), p. 12). Substrates with pores having widths exceeding about 50 nm are called macroporous. Substrates with pores having widths not exceeding about 2 nm are called microporous. Substrates with pores having widths in the range of about 2 nm to about 50 nm are called mesoporous.

Porous substrates in the macroporous range may possess a structure such that transport of a species out of the pores is subject to the same boundary layer hinderance described earlier since transport of species out of the pores is limited by the accessibility of the sites associated with species within the pores. Such boundary layer hinderance may become even more pronounced as the pore sizes of various substrates become smaller and smaller (e.g., mesoporous and microporous) because of the increased surface area of such substrates. Furthermore, smaller pores become more subject to Knudsen diffusion, as opposed to Fickian diffusion, when the characteristic pore width becomes comparable to the mean free path of the fluid molecules. Under such conditions, forced convection may play an important role in removing species from the pores of the substrate. Thus, embodiments of the invention for removing species from a substrate may be employed with such porous substrates.

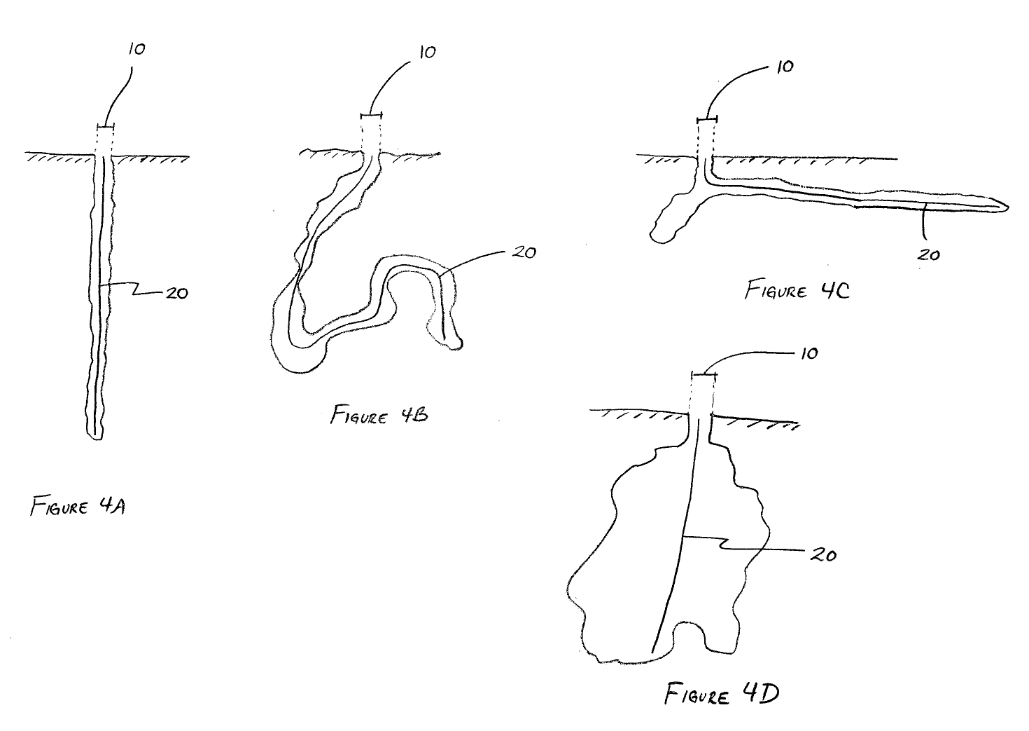

A third example of substrates that may advantageously utilize embodiments of the invention is illustrated by the void diagrams in FIGS. 4A-4D. Substrates having voids in which the size of the opening of the void 10 is smaller than the extent of the void (e.g., as measured by a penetration dimension 20 as shown in FIGS. 4A, 4B, 4C, and 4D) tend to develop boundary layers that limit transport of material out of the voids under steady fluid flow conditions. Accessibility of sites within the void are limited by the size of the opening. Thus, embodiments of the invention may be particularly useful in transporting species out of such voids.

Some substrates that possess traits as discussed by the previous examples include catalysts used in heterogeneous catalysis applications, materials used to adsorb/desorb species from fluids including packings in fixed and fluidized beds for separation processes, and particular zeolites. Other substrates also include materials used in conjunction with semiconductors, as discussed more extensively below.

Analogous to removal a species, another embodiment of the invention is directed toward inserting a new species into the void of a substrate. The method includes introducing a filling fluid into a vessel that contains the substrate, while setting the pressure in the vessel at an elevated level. The pressure in the vessel is maintained at the elevated level for a predetermined period of time. The filling fluid contains the new species to be inserted into the voids of the substrate. Next, the pressure is lowered by removing fluid from the vessel. The pressure-vent cycle steps of introducing the filling fluid, maintaining the pressure for a predetermined period of time, and lowering the pressure are carried out at least once more.

The method advantageously allows the transport of a new species to the void areas in a shorter amount of time, and with a smaller amount of filling fluid, relative to the prior art method of maintaining a constant flow of filling fluid exposed to the voids of the substrate. Since the transport phenomena principles are analogous to the removal of species from a substrate, embodiments of the invention directed to species removal can be practiced with embodiments for species insertion. For example, filling fluids that may be utilized include gases such as hydrogen or inert gases, analogous to those utilized as purging fluids in the removal of species embodiments.

Methods for inserting or removing species from the voids of a substrate may be modified to include causing a chemical reaction. For example, in methods of species removal, the chemical reaction may involve the purging fluid acting inside or outside the voids. Such a reaction may produce the ultimate species to be removed from a void, or may result in the production of other products. In methods of species insertion, a species carried by the filling fluid may induce a chemical reaction in the voids of the substrate. The chemical reaction in the voids may involve components of the filling fluid, or purging fluid, acting as catalysts, reactants, or intermediaries of the reaction. As well the chemical reaction may occur outside the voids of the substrate, the product or intermediaries of the reaction being transported into the voids by the pressure-vent cycling. All these aspects, among others apparent to those skilled in the art, are within the scope of these modified embodiments of the invention.

Methods for inserting or removing species from the voids of a substrate may also be modified such that the elevated level of pressure, lower level of pressure, or predetermined holding time of pressure at the elevated level may be altered during one or more cycles of pressure-vent cycling. Such modifications can induce changes in the conditions of forced convection, and may help accelerate insertion or removal of species from the substrate or help economize the use of filling fluids or purging fluids.

Semiconductor Substrate Processing

Particular embodiments of the present invention are directed toward semiconductor substrate processing. Semiconductor substrates include the full scope of materials that are used in processing and producing semiconductors which are utilized in integrated circuits, photovoltaic cells, light emitting diodes, and other devices. Some examples of such substrates include wafers constructed with silicon, gallium arsenide and/or germanium, and crystals such as indium gallium nitride crystals.

In one example of semiconductor processing, wafers are cleansed with deionized (“DI”) water to remove chemicals associated with previous wafer processing steps. Subsequent rinsing with a mixture of dilute isopropyl alcohol (“IPA”) in DI water is performed, followed by the use of a purging gas such as nitrogen or air delivered at a high flow rate. Alternatively, a bake-out step may be utilized to dry the wafer. Residual IPA and heavier hydrocarbons, however, may be retained on the wafer surface following the use of a high flow rate purging gas or bake-out step. Thus, processed clean dry air with moisture vapor is utilized to remove the residual IPA and hydrocarbons. Alternatively, nitrogen, helium, or a mixture of the two may be used.

The earlier discussed methods of removing a species from a substrate may be applied to semiconductor substrates to improve the ability to remove a contaminant or residue from a previous process step, using less cleansing fluid and performing the cleaning more quickly relative to conventional methods. In the context of the above example, processed clean dry air with moisture vapor may act as a purging fluid to remove the hydrocarbons and IPA. Other species that may be removed include water, residual acids and bases, and siloxanes.

Purging fluids that may be utilized include any of the purging gases or fluids previously mentioned in other embodiments of the application, including liquids (e.g., liquid carbon dioxide). In particular, purging fluids may include fluids that contain oxygen gas mixtures and/or water gas mixtures, as described in co-pending U.S. patent application Ser. No. 10/683,903 filed Oct. 10, 2003, and Ser. No. 10/683,904 filed Oct. 10, 2003, both of which are incorporated herein by reference in their entirety.

Thus, in one particular embodiment of the invention, a method for removing a species from a semiconductor substrate includes introducing a purging fluid into a vessel that contains the semiconductor substrate. While the purging fluid is introduced, the pressure in the vessel is set at an elevated level. The elevated pressure level is maintained for a predetermined period of time. Next the pressure is lowered to a lower level by removing fluid from the vessel. The removed fluid includes the species to be removed. The steps of introducing purging fluid, maintaining the pressure at a predetermined level, and lowering the pressure are repeated at least once more.

The pressure levels and holding times utilized by the above embodiment may be any that facilitate the removal of the desired species from the semiconductor substrate. In some processing instances, the elevated pressure is about atmospheric pressure and the lower level is subatmospheric, being, for example, several orders of magnitude lower than atmospheric.

In one particular example, a rinse of a wafer with a mixture of IPA and water is performed to remove chemicals associated with semiconductor fabrication. A venturi pump is utilized to lower the pressure to a level of about 10⁻¹ atmospheres to 10⁻² atmospheres, as determined by the operator. Pressure may be elevated to a higher level using a purging fluid. Either compressed air at about 100 psia or bubbled liquid nitrogen, providing a nitrogen gas source of about 150 psig, may be used as example of purging fluids. Hold times of the elevated pressures may be on the order of tens of seconds; pressure vent cycles may utilize about 100 cycles in particular practices of the method. The wafer may be held at room temperature, or heated, while pressure-vent cycling is performed.

Pressure-vent cycling may especially facilitate removal of species from different types of semiconductor substrates. For example, wafers and other semiconductor substrates may have structural features, such as vias, contacts, and deep trenches, in which transport of species into and out of the features is facilitated by pressure-vent cycling. If the opening size to a feature is smaller than the penetration dimension of the feature, accessibility to sites in the feature is limited, and pressure-vent cycling may improve transport to and away from such sites. The high aspect ratio features of some semiconductor substrates may advantageously utilize the method previously described, in analogy to the high surface area/voided substrates generally discussed earlier. As well, wafers with structures that are about 100 nm or smaller in today's cutting edge chips, requiring process cleansing to preserve the low k nature of the high aspect ratio features, may also utilize the methods discussed herein. However, even semiconductor substrates with feature sizes down to about 2 nm may advantageously utilize embodiments of the invention. Indeed, even bare wafers may have a substantial surface area (e.g., specific surface area of about 1 m²/g to about 10 m²/g) in which embodiments of the invention may find suitable application.

Pressure-vent cycling may also be used to selectively remove a particular species from a substrate. For example, during the processing of semiconductor substrates, hydrogen fluoride (HF) may be used to etch the surface of the substrate. Though purging fluids such as dry air may be utilized to remove the HF and water species from the substrate with pressure-vent cycling, residual HF may persist with the substrate due to the affinity of HF to associate with the substrate surface. Using humidified air as the purging fluid in a set of pressure-vent cycles may effectively remove the HF from the substrate, though the water associated with the substrate remains. Subsequent pressure-vent cycling with dry air acting as a purging fluid may then be performed to reduce the water associated with the substrate. Alternatively, the HF and water may be removed by utilizing a set of pressure-vent cycles that begin by utilizing humid air as a purging fluid. Subsequent cycles introducing serially less humid air as the purging fluid such that as HF is removed, then the water associated with the substrate may also be removed. Though the selective removal of species from a substrate is exemplified here by the specific species of HF and water, those of ordinary skill in the art will recognize other species in which pressure-vent cycling may be applied with particular purging fluids to selectively remove one or more species, i.e., embodiments of the invention may utilize a second purging fluid in one or more subsequent repetitions that differs in content from the purging fluid initially utilized. As well, embodiments of the invention may selectively remove a species without regard for whether a semiconductor substrate is utilized.

Embodiments of the invention also utilize pressure-vent cycling to deliver a new species to a semiconductor substrate, wherein a filling fluid is used to transport the new species to the semiconductor substrate. Delivering a new species to a substrate has particular uses in semiconductor processing. For example, a filling fluid may act as a “healing” fluid when inserted into features of a semiconductor substrate. In particular, supercritical carbon dioxide (“SCCO₂”) has shown particular promise in drying wafers and repairing low k wafer features with sizes below 65 nm (Lester, Semiconductor International, Feb. 1, 2003). Exposing SCCO₂ to such features aids in the removal of accumulated water, lowers the k value to design specifications, and may also simultaneously repair damage to the surface of the feature through reactive coupling. Mixtures of SCCO₂ with small droplets of water may also create surfactant structures that can dissolve unwanted inorganics, such as copper, in particular regions. By utilizing a method of pressure-vent cycling, a purging fluid of SCCO₂ may be utilized to remove impurities from, and repair damage to, a semiconductor substrate while minimizing the time and amount of SCCO₂ required.

Other healing fluids may also be utilized. For example, a healing fluid may include trimethylsilyl chloride or hexamethyl disilazane. The healing fluid may be the fluid itself, or the healing fluid may comprise a carrier fluid with another component that acts to repair damage. Other healing fluids, as recognized by those skilled in the art, may also be utilized in embodiments of the invention.

In a preferred alternative embodiment of the invention, gaseous state fluids, such as nitrogen, air, or argon, may be used as a carrier to deliver a healing agent or as a purging fluid. Use of such fluids may provide an advantage over using SCCO₂ because of the ease of operation of using gaseous phase fluids at lower pressures, hundreds of pounds per square inch versus thousands of pounds per square inch for supercritical fluids. As well, operation at lower pressures may result in a lower expenditure of capital equipment to perform methods associated with embodiments of the invention.

Species delivered to, or inserted into the structural features of, a semiconductor substrate may also act to passivate the surface of the semiconductor substrate (e.g., water vapor), or to cause a chemical reaction. The latter embodiments of the invention include ones analogous to those described earlier for more general substrates, and to the oxidation induced by hydrogen on surfaces of gas purifier substrates. Similarly, such reaction products can be removed from the semiconductor substrate structural features utilizing the pressure-vent cycling method previously described. Chemical reactions may also involve a purging fluid, during removal of a species, in which the purging fluid does not help produce the species to be removed.

While this invention has been particularly shown and described with references to preferred embodiments thereof, it will be understood by those skilled in the art that various changes in form and details may be made therein without departing from the scope of the invention encompassed by the appended claims.

1. A method for removing a species from a semiconductor substrate, comprising:
a) introducing a purging fluid into a vessel containing the semiconductor substrate while setting pressure in the vessel at an elevated level;
b) maintaining the pressure in the vessel at the elevated level for a predetermined period of time;
c) lowering the pressure in the vessel to a lower level by removing fluid from the vessel, the fluid including the species; and
d) repeating steps a), b) and c) at least once, thereby removing the species from the semiconductor substrate.

2. The method of claim 1, wherein the species is removed from within a structural feature of the semiconductor substrate.

3. The method of claim 2, wherein the structural feature has an opening size smaller than a penetration dimension of the structural feature.

4. The method of claim 2, wherein the structural feature is a high aspect ratio feature.

5. The method of claim 2, wherein the structural feature has a size smaller than about 100 nm.

6. The method of claim 2, wherein the structural feature has a size larger than about 2 nm.

7. The method of claim 1, wherein the species is a member of the group consisting of water, isopropyl alcohol, hydrocarbons, siloxanes, acids, and bases.

8. The method of claim 1, wherein the purging fluid includes at least one of air, argon, nitrogen, helium, carbon dioxide, trimethylsilyl chloride, hexamethyl disilazane, oxygen, water, and mixtures thereof.

9. The method of claim 8, wherein the purging fluid includes dry air and water.

10. The method of claim 1, wherein the semiconductor substrate includes a low k dielectric material.

11. The method of claim 1, wherein at least one of step a) and step b) includes repairing damage to the semiconductor substrate by exposing the semiconductor substrate to the purging fluid.

12. The method of claim 11, wherein at least one of step a) and step b) includes repairing damage to a structural feature of the semiconductor substrate.

13. The method of claim 11, wherein the purging fluid is a gas at the elevated pressure.

14. The method of claim 1, wherein at least one of step a) and step b) includes passivating a surface of the semiconductor substrate by exposing the semiconductor substrate to the purging fluid.

15. The method of claim 1, wherein lowering the pressure includes selectively removing the species from the semiconductor substrate relative to a set of species present in the semiconductor substrate.

16. The method of claim 1, wherein the lower level of pressure is subatmospheric.

17. The method of claim 1, wherein repeating steps a), b) and c) includes changing at least one of the elevated level, the lower level, and the predetermined period of time during at least one repetition of steps a), b) and c).

18. The method of claim 1, wherein repeating steps a), b) and c) includes utilizing a second purging fluid in place of the purging fluid during at least one repetition of steps a), b) and c), the second purging fluid having a different composition than the purging fluid.

19. The method of claim 1, wherein at least one of step a) and step b) includes causing a chemical reaction involving the purging fluid.

20. The method of claim 19, wherein causing the chemical reaction includes producing the species to be removed.

21. A method of delivering a new species to a semiconductor substrate, comprising:
a) introducing a filling fluid comprising the new species into a vessel while setting pressure in the vessel at an elevated level, the vessel containing the semiconductor substrate;
b) maintaining the pressure in the vessel at the elevated level for a predetermined period of time;
c) lowering the pressure in the vessel to a lower level by removing fluid from the vessel; and
d) repeating steps a), b) and c) at least once, thereby delivering the new species to the semiconductor substrate.

22. The method of claim 21, wherein the semiconductor substrate includes a structural feature, and delivering the new species includes inserting the new species into the structural feature of the semiconductor substrate.

23. The method of claim 22, wherein an opening size of the structural feature is smaller than a penetration dimension of the structural feature.

24. The method of claim 21, wherein at least one of step a) and step b) includes passivating a surface of the semiconductor by exposing the surface to the new species.

25. The method of claim 21, wherein at least one of step a) and step b) includes causing a chemical reaction involving the new species.

26. The method of claim 21, wherein at least one of step a) and step b) includes repairing damage to the semiconductor substrate by exposing the semiconductor substrate to the new species.

27. The method of claim 21, wherein repeating steps a), b) and c) includes changing at least one of the elevated level, the lower level, and the predetermined period of time during at least one repetition of steps a), b) and c).

28. A method for removing a species from a substrate, comprising:
a) introducing a purging fluid into a vessel containing the substrate while setting pressure in the vessel at an elevated level, the purging fluid being substantially free of the species;
b) maintaining the pressure in the vessel at the elevated level for a predetermined period of time;
c) lowering the pressure in the vessel to a lower level by removing fluid from the vessel, the fluid including the species, the species being removed from voids in the substrate; and
d) repeating steps a), b), and c) at least once, thereby removing the species from the substrate.

29. The method of claim 28, wherein the voids are pores in the nanoporous size range.

30. The method of claim 29, wherein the voids are pores in the mesoporous size range.

31. The method of claim 29, wherein of the voids are pores in the microporous size range.

32. The method of claim 28, wherein the voids are pores in the macroporous size range.

33. The method of claim 28, wherein the voids have an opening size smaller than a penetration dimension of the voids.

34. The method of claim 28, wherein the temperature in the vessel is maintained in the range of about 50° C. to about 400° C.

35. The method of claim 28, wherein steps a), b), and c) are repeated between about 50 and about 500 times.

36. The method of claim 28, wherein each step b) is continued for a period of about 1 second to about 10 minutes.

37. The method of claim 28, wherein the purging fluid is a mixture of plural fluids.

38. The method of claim 37, wherein at least one of the plural fluids is present in the mixture in a concentration in the range of about 50 ppm to about 5 percent of said mixture.

39. The method of claim 28, wherein the purging fluid is a bulk gas, a speciality gas or a gas mixture.

40. The method of claim 39, wherein the purging fluid comprises hydrogen, oxygen, nitrogen, argon, hydrogen chloride, ammonia, air, carbon dioxide, helium, silane, germane, diborane, phosphine, arsine or mixtures thereof.

41. The method of claim 37, wherein the mixture is about 5% hydrogen and about 95% nitrogen.

42. The method of claim 28, wherein the species is a member of the group consisting of oxygen, hydrogen, carbon monoxide, carbon dioxide, water, a non-methane hydrocarbon, and an oxidation byproduct.

43. The method as in claim 28, wherein the substrate has a surface area of at least about 1 m²/g.

44. The method of claim 28, wherein at least one of step a) and step b) includes causing a chemical reaction to form the species in the voids.

45. The method of claim 28, wherein said steps a), b), and c) are repeated until the temperature within the vessel passes through a maximum value and decreases to a substantially constant equilibrium value.

46. The method of claim 28, wherein repeating steps a), b) and c) includes changing at least one of the elevated level, the lower level, and the predetermined period of time during at least one repetition of steps a), b) and c).

47. The method of claim 28, wherein repeating steps a), b) and c) includes utilizing a second purging fluid in place of the purging fluid during at least one repetition of steps a), b) and c), the second purging fluid having a different composition than the purging fluid.

48. A method for removing a species from a substrate, comprising:
a) introducing a purging fluid into a vessel containing the substrate while setting pressure in the vessel at an elevated level, the substrate having a surface area of at least about 1 m²/g; the purging fluid being substantially free of the species;
b) maintaining the pressure in the vessel at the elevated level for a predetermined period of time;
c) lowering the pressure in the vessel to a lower level by removing fluid from the vessel, the fluid including the species to be removed; and
d) repeating steps a), b), and c) at least once, thereby removing the species from the substrate.

49. A method for inserting a new species into a substrate, comprising:
a) introducing a filling fluid comprising the new species into a vessel while setting pressure in the vessel at an elevated level, the vessel containing the substrate with voids;
b) maintaining the pressure in the vessel at the elevated level for a predetermined period of time, the new species being inserted into the voids;
c) lowering the pressure in the vessel to a lower level by removing fluid from the vessel; and
d) repeating steps a), b) and c) at least once, thereby inserting the new species into the substrate.

50. The method of claim 49, wherein at least one of step a) and step b) includes causing a chemical reaction in the voids involving the new species.

51. The method of claim 50, wherein the substrate has an inorganic oxide surface.

52. The method of claim 50, wherein the filling fluid includes at least one of hydrogen and an inert gas.

53. The method of claim 49, wherein the voids have an opening size smaller than a penetration dimension of the voids.

54. The method of claim 49, wherein the substrate has a surface area of at least about 1 m²/g.

55. The method of claim 49, wherein repeating steps a), b) and c) includes changing at least one of the elevated level, the lower level, and the predetermined period of time during at least one repetition of steps a), b) and c).

56. A method for regenerating a gas purification substrate, comprising:
a) introducing a purging fluid into a vessel containing the gas purification substrate while setting pressure in the vessel at an elevated level;
b) maintaining the pressure in the vessel at the elevated level for a predetermined period of time;
c) lowering the pressure in the vessel to a lower level by removing fluid from the vessel; and
d) repeating steps a), b) and c) at least once, thereby regenerating the gas purification substrate.
